(19) United States
(12) Patent Application Publication
(10) Pub. No.: US 2007/0096212 A1
(43) Pub. Date: May 3, 2007

(54) Semiconductor device and method for fabricating the same

(76) Inventors: Yoshihiro Sato, Hyogo (JP); Hisashi Ogawa, Osaka (JP)

Correspondence Address: MCDERMOTT WILL & EMERY LLP, 600 13TH STREET, N.W., WASHINGTON, DC, 20005-3096, US

(21) Appl. No.: 11/583,846

(22) Filed: Oct. 20, 2006

(30) Foreign Application Priority Data
Oct. 27, 2005 (JP) 2005-312351

(51) Int. Cl. H01L 27/12; H01L 21/4763; H01L 27/01; H01L 31/0392

(52) U.S. Cl. 257/350; 438/622

(57) ABSTRACT

A semiconductor device includes a fully silicided first gate interconnect formed on a semiconductor substrate, a first sidewall formed on a side of the first gate interconnect, and impurity diffusion layers formed in an active region of the semiconductor substrate. A shared contact plug is formed in an interlayer dielectric formed on the semiconductor substrate so as to be connected to the first gate interconnect and associated one of the impurity diffusion layers. The first gate interconnect is formed, at its part connected to the shared contact plug, with a projection part projecting beyond the first sidewall.

### CROSS-REFERENCE TO RELATED APPLICATIONS

The disclosure of Japanese Patent Application No. 2005-312351 filed on Oct. 27, 2005 including specification, drawings and claims is incorporated herein by reference in its entirety.

### BACKGROUND OF THE INVENTION

(1) Field of the Invention

The present invention relates to semiconductor devices and methods for fabricating the same, and more particularly relates to semiconductor devices whose gate interconnects are fully silicided and each have a local interconnect structure and methods for fabricating the same.

(2) Description of Related Art

In recent years, with an increasing degree of integration, increasing functionality and increasing operating speed of semiconductor devices, there are increasing demands for miniaturization of semiconductor devices. With the miniaturization of semiconductor devices, the tendency has been toward increases in the contact and interconnect resistances of gate electrodes. In order to reduce the contact and interconnect resistances, gate electrodes are silicided.

The interconnect resistance is reduced by allowing interconnects which are formed inside a semiconductor device and through which gate electrodes are connected to source/drain diffusion regions to each have a local interconnect structure.

For example, a shared contact plug through which a gate electrode is electrically connected to an associated source or drain diffusion layer can be formed as follows: A contact hole is formed in an interlayer dielectric to expose a part of the gate electrode and a part of the source or drain diffusion layer, and the formed contact hole is filled with a conductive material (see, for example, Japanese Unexamined Patent Publication No. 8-181205).

FIG. 8 is a cross-sectional view illustrating the structure of a known semiconductor device including a shared contact plug. As illustrated in FIG. 8, the known semiconductor device includes a gate electrode 103 of silicon formed on a silicon substrate 101 with a gate oxide film 102 interposed therebetween. A silicide layer 104 is formed on the gate electrode 103, and sidewall oxide films 105 are formed on both sides of a combination of the gate electrode 103 and the gate oxide film 102. The known semiconductor device further includes source/drain regions 106 formed in regions of the silicon substrate 101 located to both sides of the gate electrode 103. Silicide layers 107 are formed on the source/drain regions 106, respectively, and an interlayer oxide layer 108 is formed to cover the gate electrode 103 and the source/drain regions 106. A contact hole 109 is formed in the interlayer oxide film 108 to expose a part of the gate electrode 103 and a part of associated one of the source/drain regions 106. A shared contact plug 110 is formed to fill the contact hole 109. The shared contact plug 110 is electrically connected to the gate electrode 103 and the associated source/drain region 106.

Use of such a shared contact plug reduces the size of a semiconductor device, and when the semiconductor device has a local interconnect, this reduces the interconnect resistance of the semiconductor device. Therefore, a semiconductor device that operates at a high speed can be achieved.

### SUMMARY OF THE INVENTION

However, after a known semiconductor device including a shared contact plug was studied in various manners, the present inventors found the following problems. With further miniaturization of gate electrodes, the structure of a semiconductor device in which a silicide layer 104 is formed on a gate electrode 103 of silicon increases the interconnect resistance and reduces the contact area between the gate electrode 103 and a shared contact plug 110. This increases the contact resistance between the gate electrode 103 and the shared contact plug 110.

On the other hand, in recent years, it has been considered to fully silicide gate electrodes with the aim of increasing the operating speed of semiconductor devices. The interconnect resistance is expected to be reduced by fully siliciding gate electrodes. However, there still occurs such a problem that a reduction in the contact area between a gate electrode and a shared contact plug leads to an increase in the contact resistance.

The present invention is made to solve the known problems, and its object is to achieve a semiconductor device whose gate electrode has a low interconnect resistance and which has a low contact resistance between the gate electrode and a shared contact plug.

In order to accomplish the above-described object, a semiconductor device of the present invention is configured so that its gate interconnect has a projection part projecting beyond a sidewall.

To be specific, a semiconductor device according to the present invention includes: an isolation region formed in a semiconductor substrate; an active region formed in the semiconductor substrate so as to be surrounded by the isolation region; a fully silicided first gate interconnect formed on the semiconductor substrate; an insulative first sidewall formed on a side of the first gate interconnect; impurity diffusion layers formed in the active region; an interlayer dielectric formed on the semiconductor substrate to have an opening exposing an area covering a part of the first gate interconnect and a part of associated one of the impurity diffusion layers; and a contact plug made of a conductive material with which the opening is filled and connected to the first gate interconnect and the associated impurity diffusion layer. The first gate interconnect is formed, at its part connected to the contact plug, with a projection part projecting beyond the first sidewall.

According to the semiconductor device of the present invention, the contact area between a shared contact plug and a gate interconnect can be increased. This can reduce the contact resistance between the shared contact plug and the gate interconnect. Furthermore, since the gate interconnect is fully silicided, this can reduce the interconnect resistance of the gate interconnect.

In the semiconductor device of the present invention, the projection part of the first gate interconnect preferably covers part of the entire surface of the first sidewall. This structure allows the sidewall to be protected by the projection part in formation of a contact hole for the shared contact plug. Therefore, it is less likely to etch the sidewall in the formation of the contact hole. This can prevent a shallow impurity diffusion layer from being exposed at the bottom of the contact hole. As a result, a semiconductor device can be achieved which prevents a short circuit from being caused between the shared contact plug and the shallow impurity diffusion layer and avoids a reduction in junction breakdown voltage and an increase in junction leakage current.

In the semiconductor device of the present invention, the first gate interconnect preferably includes a first gate electrode and a first interconnect formed continuously with the first gate electrode. The contact plug is preferably connected to the first interconnect. The first interconnect is preferably formed, at its part connected to the contact plug, with the projection part. The height of the first gate electrode is preferably equal to or lower than that of the first sidewall. With this structure, when in addition to the shared contact plug a contact plug is formed so as to be connected to a source or drain region, a short circuit can be prevented from being caused between the contact plug and the gate electrode.

In the semiconductor device of the present invention, the height of a part of the first sidewall formed on a side of a part of the first interconnect formed with the projection part is preferably lower than that of a part of the first sidewall formed on a side of the first gate electrode. With this structure, a projection part is easily formed to cover part of the entire surface of the sidewall, and the sidewall can be protected with reliability.

In the semiconductor device of the present invention, the first gate interconnect is preferably formed on the active region with a first gate insulating film interposed therebetween.

It is preferable that the semiconductor device of the present invention further includes: a fully silicided second gate interconnect formed on the semiconductor substrate at some distance from the first gate interconnect; a second gate insulating film formed on the active region and under the second gate interconnect; and an insulative second sidewall formed on a side of the second gate interconnect. The associated impurity diffusion layer is preferably a source/drain region formed in a region of the active region between the second gate interconnect and the first gate interconnect.

In the semiconductor device of the present invention, it is preferable that the source/drain region includes a first diffusion layer formed in a region of the active region located to a side of the second gate interconnect and a second diffusion layer formed in a region of the active region located further from the second gate interconnect than the first diffusion layer and deeper than the first diffusion layer and the contact plug is electrically connected to the second diffusion layer.

In the semiconductor device of the present invention, the second gate interconnect preferably includes a second gate electrode and a second interconnect formed continuously with the second electrode. The second gate electrode is preferably formed on the second gate insulating film. The height of the second gate electrode is preferably equal to or lower than that of the second sidewall.

In the semiconductor device of the present invention, the first gate interconnect is preferably made of nickel silicide.

It is preferable that the semiconductor device of the present invention further includes an underlayer protecting film formed between the interlayer dielectric and the semiconductor substrate.

In the semiconductor device of the present invention, it is preferable that the contact plug is electrically connected through a silicide layer to the associated impurity diffusion layer.

A method for fabricating a semiconductor device according to the present invention includes the steps of: (a) forming an isolation region in a semiconductor substrate and forming an active region in the semiconductor substrate so as to be surrounded by the isolation region; (b) after the step (a), forming a first gate interconnect formation film made of a semiconductor material containing silicon on the semiconductor substrate; (c) forming an insulative first sidewall on a side of the first gate interconnect formation film; (d) after the step (b), forming impurity diffusion layers in the active region; (e) after the steps (c) and (d), fully siliciding the first gate interconnect formation film, thereby forming a first gate interconnect; and (f) after the step (e), forming an interlayer dielectric to entirely cover the semiconductor substrate; (g) etching the interlayer dielectric, thereby forming an opening in a region of the interlayer dielectric covering a part of the first gate interconnect and a part of associated one of the impurity diffusion layers; and (h) filling the opening with a conductive material, thereby forming a contact plug electrically connected to the first gate interconnect and the associated impurity diffusion layer, wherein in the step (e), the first gate interconnect is formed, at its part connected to the contact plug, with a projection part projecting beyond the first sidewall.

The method of the present invention allows the first sidewall to be protected by the projection part in formation of a contact hole for the shared contact plug. Therefore, it is less likely to etch the first sidewall in the formation of the contact hole. This can prevent a shallow impurity diffusion layer from being exposed at the bottom of the contact hole. As a result, a semiconductor device can be achieved which prevents a short circuit from being caused between the shared contact plug and the shallow impurity layer and avoids a reduction injunction breakdown voltage and an increase injunction leakage current.

In the method of the present invention, in the step (e), the projection part of the first gate interconnect is preferably formed to cover a part of the entire surface of the first sidewall.

In the method of the present invention, it is preferable that in the step (e), the first gate interconnect formation film is formed into the first gate interconnect formed of a first gate electrode and the first gate interconnect formed continuously with the first gate electrode. It is preferable that the method further comprises the step of (i) between the steps (d) and (e), etching a part of the first gate interconnect formation film that will be a first gate electrode, thereby allowing the part of the first gate interconnect formation film that will be a first gate electrode to become thinner than a part of the first gate interconnect formation film that will be a part of the first interconnect formed with the projection part. In the step (e), the height of the first gate electrode is preferably equal to or lower than that of the first sidewall.

In the method of the present invention, it is preferable that in the step (i), the thickness of a part of the first gate interconnect formation film that will become a part of the first gate interconnect formed with the projection part is more than half the height of the first sidewall. This structure permits formation of the projection part with reliability.

In the method of the present invention, it is preferable that in the step (i), the thickness of a part of the first gate interconnect formation film that will become the first gate electrode is less than half the height of the first sidewall. With this structure, a region of a gate interconnect on which a shared contact plug is not formed can be formed as usual without projecting beyond a sidewall.

It is preferable that the method of the present invention further includes the step of (j) between the steps (i) and (e), allowing the height of a part of the first sidewall formed on the side of the part of the first gate interconnect formation film that will be a part of the first gate interconnect formed with the projection part to have a lower height than that of the first sidewall formed on a side of the part of the first gate interconnect formation film that will be the first gate electrode. With this structure, the projection part is easily formed to cover part of the entire surface of the first sidewall.

In the method of the present invention, it is preferable that in the step (j), the height of a region of the first sidewall on which the projection part is to be formed is lower than that of an associated region of the first gate interconnect formation film.

It is preferable that the method of the present invention further includes the step of (k) between the steps (e) and (f), forming an underlayer protecting film to entirely cover the semiconductor substrate. In the step (f), the interlayer dielectric is preferably formed to cover the underlayer protecting film.

In the method of the present invention, it is preferable that in the step (b), a second gate interconnect formation film made of a semiconductor material containing silicon is formed on the semiconductor substrate at some distance from the first gate interconnect formation film. In the step (c), an insulative second sidewall is preferably formed on a side of the second gate interconnect formation film. In the step (d), the impurity diffusion layers are preferably formed in regions of the active region located to both sides of the second gate interconnect formation film. It is preferable that in the step (e), the second gate interconnect formation film is fully silicided, thereby forming a second gate interconnect.

It is preferable that the method of the present invention further includes the step of (l) between the steps (a) and (b), forming a gate insulating film on the active region. In the step (b), the first and second gate interconnect formation films are preferably formed on the active region with the gate insulating film interposed between a combination of the first and second gate interconnect formation films and the active region.

### BRIEF DESCRIPTION OF THE DRAWINGS

FIGS. 1A and 1B illustrate a semiconductor device according to a first embodiment of the present invention, in which FIG. 1A is a plan view of the semiconductor device and FIG. 1B is a cross-sectional view taken along the line Ib-Ib in FIG. 1A.

FIGS. 2A through 2E are cross-sectional views illustrating some of process steps in a fabrication method for a semiconductor device according to the first embodiment of the present invention step by step.

FIGS. 3A through 3E are cross-sectional views illustrating some other ones of process steps in the fabrication method for a semiconductor device according to the first embodiment of the present invention step by step.

FIGS. 4A through 4C are cross-sectional views illustrating the other ones of process steps in the fabrication method for a semiconductor device according to the first embodiment of the present invention step by step.

FIGS. 5A and 5B illustrate a semiconductor device according to a second embodiment of the present invention, in which FIG. 5A is a plan view of the semiconductor device and FIG. 5B is a cross-sectional view taken along the line Vb-Vb in FIG. 5A.

FIGS. 6A through 6C are cross-sectional views illustrating some of process steps in a fabrication method for a semiconductor device according to the second embodiment of the present invention step by step.

FIGS. 7A through 7C are cross-sectional views illustrating the other ones of process steps in the fabrication method for a semiconductor device according to the second embodiment of the present invention step by step.

FIG. 8 is a cross-sectional view illustrating a semiconductor device according to a known example.

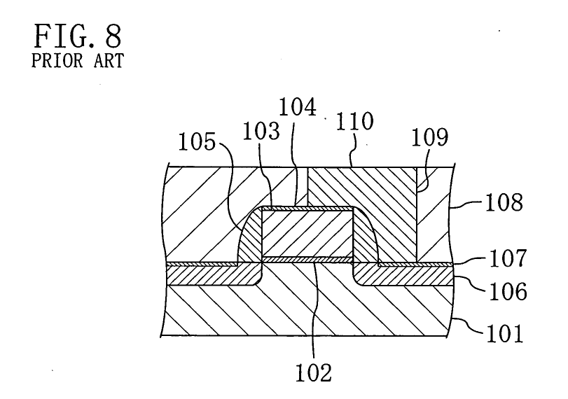

### DETAILED DESCRIPTION OF THE INVENTION

### Embodiment 1

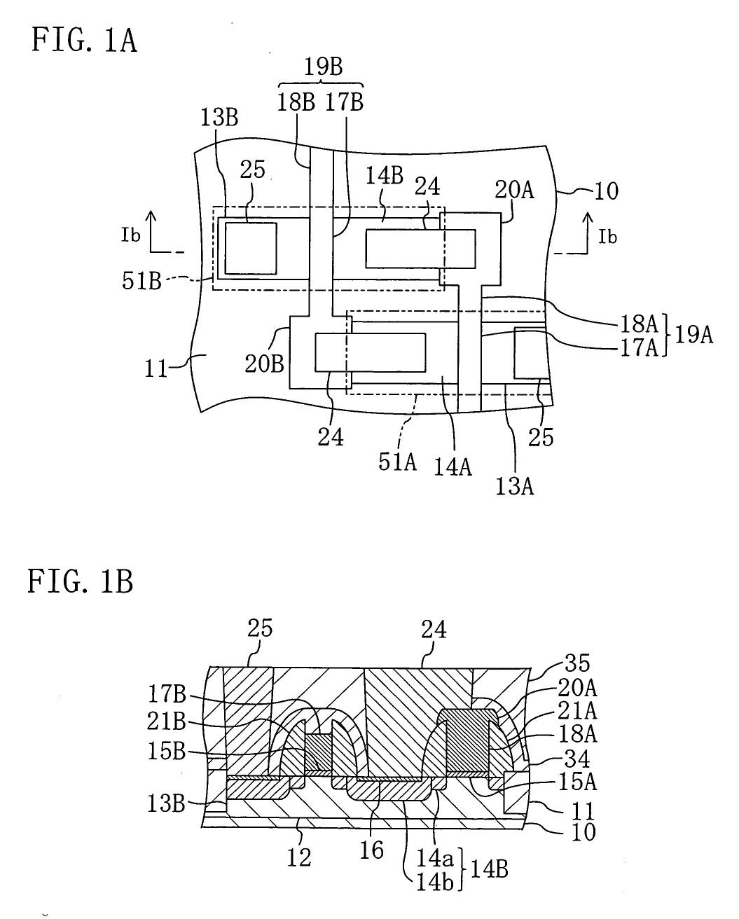

A first embodiment of the present invention will be described with reference to the drawings. FIGS. 1A and 1B illustrate a semiconductor device according to the first embodiment of the present invention. FIG. 1A illustrates a plan structure of the semiconductor device, and FIG. 1B illustrates a cross-sectional structure thereof.

FIG. 1A illustrates a first transistor 51A formed on a first active region 13A of a semiconductor substrate 10 surrounded by an isolation region 11 thereof and a second transistor 51B formed on a second active region 13B thereof. The first transistor 51A includes a fully silicided first gate electrode 17A and source/drain regions 14A formed in the first active region 13A. The second transistor 51B includes a fully silicided second gate electrode 17B and source/drain regions 14B formed in the second active region 13B. The first and second transistors 51A and 51B are both P-type MIS transistors.

As illustrated in FIG. 1B, the second transistor 51B includes a second gate insulating film 15B formed on the second active region 13B of the semiconductor substrate 10 surrounded by the isolation region 11 thereof, a second gate electrode 17B formed on the second gate insulating film 15B, second sidewalls 21B formed on both sides of the second gate electrode 17B, and source/drain regions 14B formed in regions of the second active region 13B located to both sides of the second gate electrode 17B and serving as P-type impurity diffusion layers.

The source/drain regions 14B is composed of shallow source/drain diffusion layers (extension regions or lightly-doped drain (LDD) regions) 14a formed in regions of the semiconductor substrate 10 located to both sides of the gate electrode 17B and deep source/drain diffusion layers 14b formed in regions thereof located to the outer sides of the second sidewalls 21B. Silicide layers 16 are formed on the top surfaces of the deep source/drain diffusion layers 14b.

The following layers are also formed on the second active region 13B: a first gate insulating film 15A made of the same insulating film as the second gate insulating film 15B; a fully silicided first interconnect 18A formed on the first gate insulating film 15A; and first sidewalls 21A formed on both sides of the first interconnect 18A. The first interconnect 18A has a projection part 20A projecting beyond the first sidewalls 21A and covering parts of the entire surfaces of the first sidewalls 21A and is formed continuously with the first gate electrode 17A of the first transistor 51A as illustrated in FIG. 1A. The first gate electrode 17A and the first interconnect 18A form a fully silicided first gate interconnect 19A.

As illustrated in FIG. 1A, the second gate electrode 17B is formed continuously with a fully silicided second interconnect 18B. The second gate electrode 17B and the second interconnect 18B form a fully silicided second gate interconnect 19B. The second interconnect 18B extends through the isolation region 11 toward the first active region 13A and is connected through associated one of shared contact plugs 24 to associated one of the source/drain regions 14A. The second interconnect 18B is formed, at its region on which the associated shared contact plug 24 is formed, with a projection part 20B. The second interconnect 18B formed with the projection part 20B has the same structure as the first interconnect 18A formed with the projection part 20A illustrated in FIG. 1B.

A film 34 for protecting underlayers (hereinafter, referred to as “underlayer protecting film 34”) which is formed of a silicon nitride film is formed on the semiconductor substrate 10 to cover the second gate electrode 17B, the first interconnect 18A, the first and second sidewalls 21A and 21B, and other films. An interlayer dielectric 35 made of a silicon oxide film is formed to cover the underlayer protecting film 34.

As illustrated in FIG. 1B, one of the shared contact plugs 24 is formed to cover associated one of the deep source/drain diffusion layers 14b formed in parts of the second active region 13B located to both sides of the second gate electrode 17B and part of the first interconnect 18A and pass through the interlayer dielectric 35 and the underlayer protecting film 34. One of contact plugs 25 is formed on the other one of the deep source/drain diffusion layers 14b to pass through the interlayer dielectric 35 and the underlayer protecting film 34. The contact plug 25 and the shared contact plug 24 are formed by filling contact holes with a conductive material, such as tungsten, and connected through the silicide layers 16 to the deep source/drain diffusion layers 14b.

In the semiconductor device of this embodiment, the first interconnect 18A is formed, at its part connected to associated one of the shared contact plugs 24, with a projection part 20A projecting beyond the first sidewalls 21A. The projection part 20A is wider than the other part of the first interconnect 18A. This increases the contact area between the first gate interconnect 19A and the associated shared contact plug 24. This can reduce the contact resistance between the first gate electrode 17A and the associated shared contact plug 24.

Furthermore, since the projection part 20A covers parts of the entire surfaces of the first sidewalls 21A, it functions as an etching mask in formation of contact holes passing through the interlayer dielectric 35 and the underlayer protecting film 34. This can restrain the first sidewalls 21A from being etched. In this manner, when a contact hole for formation of a shared contact plug is formed, one of the shallow source/drain diffusion layers 14a can be prevented from being exposed at the bottom of the formed contact hole. This can suppress a reduction in the junction breakdown voltage of a transistor and an increase in the junction leakage current due to shorting between the shared contact plug 24 and associated one of the shallow source/drain diffusion layers 14a.

Likewise, a second interconnect 18B is formed, at its part connected to associated one of shared contact plugs 24, with a projection part 20B projecting beyond second sidewalls 21B. The projection part 20B covers parts of the entire surfaces of the second sidewalls 21B. This reduces the contact resistance between the second gate electrode 17B and the associated shared contact plug 24.

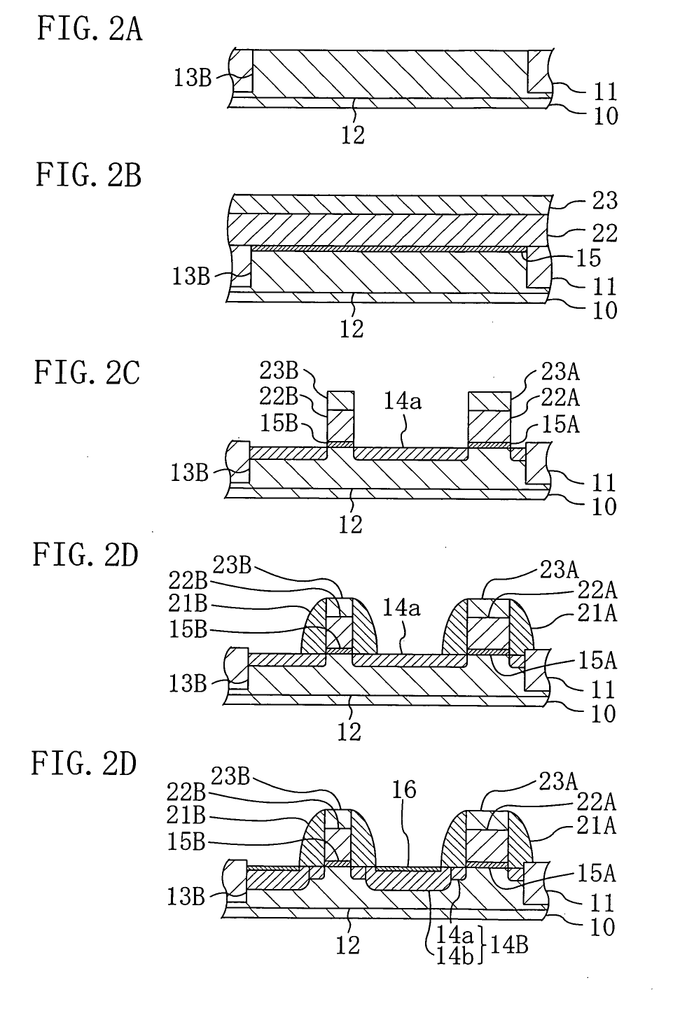

A fabrication method for a semiconductor device according to this embodiment will be described hereinafter with reference to the drawings. FIGS. 2A through 4C are cross-sectional views illustrating process steps in the fabrication method for a semiconductor device according to the first embodiment step by step. FIGS. 2A through 4C illustrate cross sections taken along the line Ib-Ib in FIG. 1A.

First, as illustrated in FIG. 2A, an isolation region 11 for electrically isolating elements from one another is formed in a semiconductor substrate 10, for example, by shallow trench isolation (STI). In this way, a second active region 13B is formed in the semiconductor substrate 10 so as to be surrounded by the isolation region 11. Subsequently, boron ions are implanted, as a P-type impurity, into the semiconductor substrate 10, thereby forming a P-type well 12.

Next, as illustrated in FIG. 2B, a 2-nm-thick gate insulating film 15 of silicon oxide is formed on the second active region 13B by dry oxidation, wet oxidation, oxidation using radical oxygen, or any other method. Subsequently, an 80-nm-thick polysilicon film 22 that will be partially formed into gate electrodes is deposited, for example, by chemical vapor deposition (CVD), to entirely cover the semiconductor substrate 10. Thereafter, in the subsequent process step, a 60-nm-thick silicon oxide film 23 that will be partially formed into a protective film for the polysilicon film 22 is formed on the polysilicon film 22, for example, by CVD. In this case, the silicon oxide film 23 is thinner than the polysilicon film 22.

Next, as illustrated in FIG. 2C, a first protective film 23A and a second protective film 23B are formed by patterning the silicon oxide film 23 into the shape of a gate interconnect (the shape in which a gate electrode and an interconnect are continuously formed) using photolithography and dry etching.

Subsequently, the polysilicon film 22 and the gate insulating film 15 are subjected to dry etching using the patterned first and second protective films 23A and 23B as masks. In this way, the following films are formed: a first film 22A for formation of a gate interconnect (hereinafter, referred to as “first gate interconnect formation film 22A”); a first gate insulating film 15A; a second film 22B for formation of a gate interconnect (hereinafter, referred to as “second gate interconnect formation film 22B”); and a second gate insulating film 15B.

Subsequently, boron ions are implanted, as a P-type impurity, into the second active region 13B using the first gate interconnect formation film 22A and the second gate interconnect formation film 22B as masks, thereby forming P-type shallow source/drain diffusion layers 14a.

An etching gas having fluorocarbon as the main ingredient need be used for etching of the silicon oxide film 23. An etching gas having chlorine or bromine as the main ingredient need be used for etching of the polysilicon film 22.

Next, as illustrated in FIG. 2D, for example, a 50-nm-thick silicon nitride film is deposited, for example, by CVD to entirely cover the semiconductor substrate 10, and then the deposited silicon nitride film is subjected to anisotropic etching. In this way, the silicon nitride film is partially removed to leave its parts formed on both sides of a combination of the first gate interconnect formation film 22A and the first protective film 23A and both sides of a combination of the second gate interconnect formation film 22B and the second protective film 23B. In this way, first sidewalls 21A are formed to continuously cover both sides of the combination of the first gate interconnect formation film 22A and the first protective film 23A, and second sidewalls 21B are formed to continuously cover both sides of the combination of the second gate interconnect formation film 22B and the second protective film 23B.

Next, as illustrated in FIG. 2E, boron serving as a P-type impurity is introduced into the second active region 13B by ion implantation using the first sidewalls 21A and the second sidewalls 21B as masks. In this way, P-type deep source/drain diffusion layers 14b are formed in regions of the second active region 13B located to both sides of the second gate interconnect formation film 22B (located further from the second gate interconnect formation film 22B than the second sidewalls 21B). In this manner, the shallow source/drain diffusion layers 14a and the deep source/drain diffusion layers 14b form source/drain regions 14B.

Subsequently, natural oxide films formed in the top surfaces of the deep source/drain diffusion layers 14b are removed, and then a 10-nm-thick nickel film (not shown) is deposited on the semiconductor substrate 10 by sputtering. Thereafter, the semiconductor substrate 10 is subjected to the first rapid thermal annealing (RTA) in a nitrogen atmosphere, for example, at a temperature of 320° C., thereby causing a reaction between silicon forming the semiconductor substrate 10 and the nickel film.

Next, the unreacted part of the nickel film is removed using a mixed acid of hydrochloric acid and a hydrogen peroxide solution, and then the semiconductor substrate 10 is subjected to the second RTA at a higher temperature than that in the first RTA (for example, 550° C.). In this way, low-resistance silicide layers 16 are formed on the respective top surfaces of the deep source/drain diffusion layers 14b.

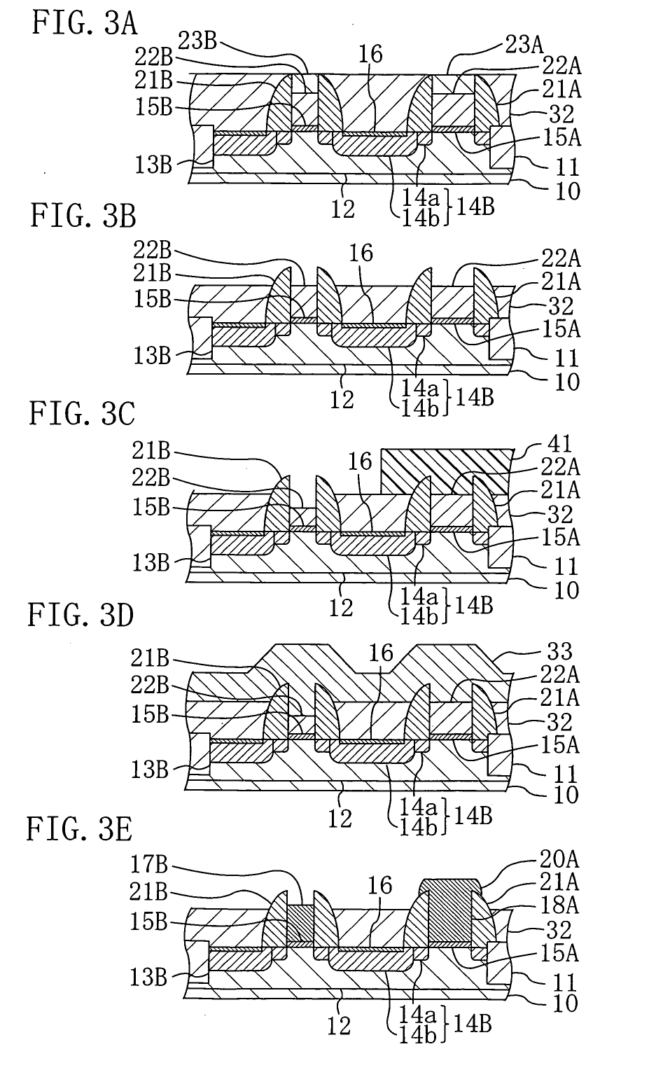

Next, as illustrated in FIG. 3A, a third protective film 32 that is made of a silicon oxide film and will be used as a mask for full silicidation of the first and second gate interconnect formation films 22A and 22B is formed to entirely cover the semiconductor substrate 10. Thereafter, the top surface of the third protective film 32 is planarized by CMP and polished until the respective top surfaces of the first and second protective films 23A and 23B are exposed.

Next, as illustrated in FIG. 3B, the first and second protective films 23A and 23B and an upper portion of the third protective film 32 are etched away by dry etching or wet etching with high selectivity of silicon oxide to silicon nitride and polysilicon until the respective top surfaces of the first and second gate interconnect formation films 22A and 22B are exposed. In order to selectively etch the silicon oxide film, for dry etching, the silicon oxide film need be subjected to reactive ion etching, for example, under the following conditions: Octafluorocyclopentene (C₅F₈), oxygen (O₂) and argon (Ar) are supplied to a reaction chamber with a pressure of 6.7 Pa at flow rates of 15 ml/min (normal conditions), 18 ml/min (normal conditions) and 950 ml/min (normal conditions), respectively, using a radio frequency (RF) output power of 1800 W for plasma generation and a bias power of 1500 W; and the substrate temperature is 0° C.

Next, as illustrated in FIG. 3C, a resist mask 41 is formed to cover part of the first gate interconnect formation film 22A that will be connected to associated one of shared contact plugs 24 in a later process step. In this process step, the resist mask 41 is formed on a region of the first interconnect formation film 22A that will be formed with a projection part 20A in a later process step. Although not shown, another resist mask is formed also on a region of the second gate interconnect formation film 22B that will be formed with a projection part 20B so as to be prevented from being etched. Subsequently, part of the first gate interconnect formation film 22A that is not covered with the resist mask 41 and part of the second gate interconnect formation film 22B that is not covered with the resist mask are etched by dry etching to each have a thickness of 40 nm.

Next, as illustrated in FIG. 3D, the resist mask 41 is removed, and then a 100-nm-thick metal film 33 of nickel is deposited on the third protective film 32 by sputtering. Subsequently, the semiconductor substrate 10 is subjected to RTA in a nitrogen atmosphere at a temperature of 400° C. This causes reactions between the first gate interconnect formation film 22A and the metal film 33 and between the second gate interconnect formation film 22B and the metal film 33, resulting in the fully silicided first and second gate interconnect formation films 22A and 22B. The metal film 33 is 1.1 times or more as thick as a region of the first gate interconnect formation film 22A that will be formed with a projection part 20A. This makes it possible to filly silicide the first and second gate interconnect formation films 22A and 22B with reliability.

Next, as illustrated in FIG. 3E, unreacted part of the metal film 33 is removed. In this way, a fully silicided first gate interconnect 19A is formed of a first interconnect 18A having a projection part 20A that projects beyond the first sidewalls 21A and a first gate electrode 17A (see FIG. 1A) that does not project beyond the first sidewalls 21 (see FIG. 1A). Simultaneously, a fully silicided second gate interconnect 19B is formed of a second interconnect 18B (see FIG. 1A) having a projection part 20B (see FIG. 1A) that projects beyond the second sidewalls 21B and a second gate electrode 17B that does not project beyond the second sidewalls 21B (see FIG. 1A).

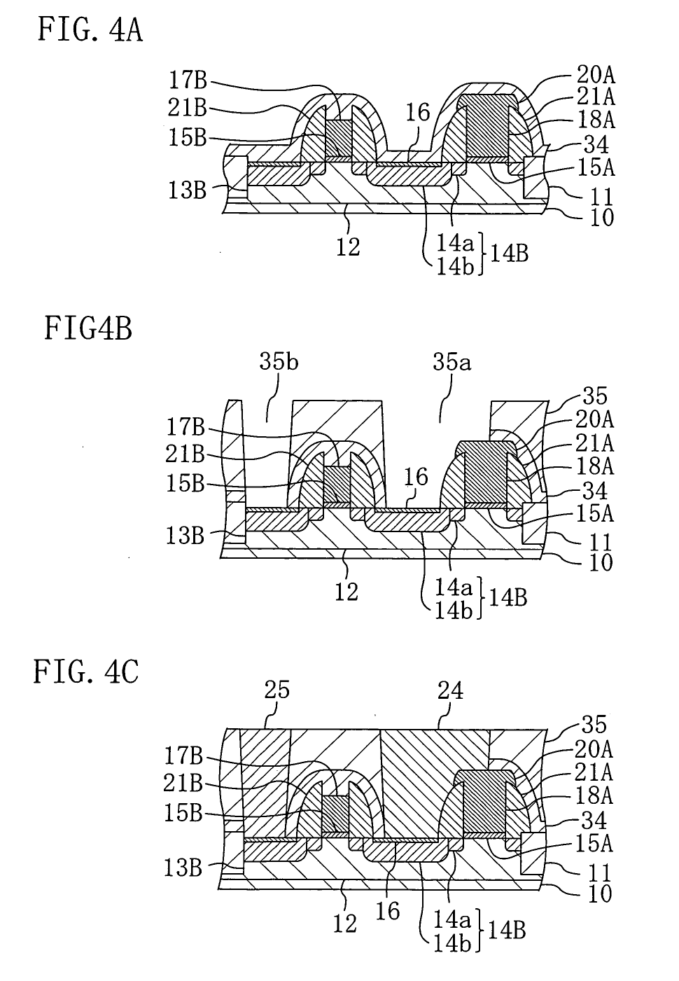

Next, as illustrated in FIG. 4A, the third protective film 32 is removed by dry etching or wet etching. Thereafter, a 50-nm-thick underlayer protecting film 34 made of a silicon nitride film is deposited, for example, by CVD to entirely cover the semiconductor substrate 10.

Next, as illustrated in FIG. 4B, an interlayer dielectric 35 made of a silicon oxide film is formed, for example, by CVD to cover the underlayer protecting film 34, and then the top surface of the interlayer dielectric 35 is planarized by CMP. Thereafter, a resist mask (not shown) is formed on the interlayer dielectric 35, and then the interlayer dielectric 35 and the underlayer protecting film 34 are subjected to dry etching using the resist mask. In this way, a first contact hole 35a is formed to expose part of associated one of the silicide layers 16 formed in the deep source/drain diffusion layers 14b, part of associated one of the first sidewalls 21A, and part of the projection part 20A of the first interconnect 18A. Simultaneously, a second contact hole 35b is formed to expose part of the other one of the silicide layers 16.

Next, as illustrated in FIG. 4C, the resist mask is removed, and then titanium (Ti) and titanium nitride (TiN) forming a barrier metal layer are deposited on the semiconductor substrate 10 by CVD to have thicknesses of 10 nm and 5 nm, respectively (not shown). Thereafter, a metal film of tungsten or any other metal is deposited on the deposited barrier metal layer.

Subsequently, a portion of the metal film deposited outside the first and second contact holes 35a and 35b and located on the top surface of the interlayer dielectric 35 is removed by CMP or an etch back process. One of shared contact plugs 24 is formed so as to be connected to associated one of the silicide layers 16 formed in the deep source/drain diffusion layers 14b and the first interconnect 18A, and one of contact plugs 25 is formed so as to be connected to the other one of the silicide layers 16.

According to the method of this embodiment, a part of the first gate interconnect formation film 22A that will be formed with the projection part 20A is thicker than the other part thereof. In such a state, the first gate interconnect formation film 22A is fully silicided. In this way, a fully silicided first gate interconnect 19A can be easily formed, at its region on which associated one of the shared contact plugs 24 is formed, with a projection part 20A. In view of the above, a semiconductor device can be easily formed which has a low contact resistance between the shared contact plug 24 and the first gate electrode 17A.

The projection part 20A of the first interconnect 18A covering parts of the entire surfaces of the first sidewalls 21A serves as an etching mask for formation of the first contact hole 35a. This can restrain the first sidewalls 21A from being etched. In view of the above, a semiconductor device can be fabricated which, even with the formation of the shared contact plugs 24, prevents a reduction in the junction breakdown voltage of a transistor and an increase in the junction leakage current thereof.

In order to form the projection part 20A covering parts of the entire surfaces of the first sidewalls 21A, the first gate interconnect formation film 22A need be fully silicided under the following conditions: The thickness of a region of the first gate interconnect formation film 22A that will be formed with the projection part 20A is half or more the height of each first sidewall 21A.

In the method of this embodiment, the height of each first sidewall 21A is substantially equal to the sum of the thickness of a region of the first gate interconnect formation film 22A that will be formed with a projection part 20A and the thickness of the first protective film 23A. In this embodiment, the region of the first gate interconnect formation film 22A that will be formed with the projection part 20A has a thickness of 80 nm, and the first protective film 23A has a thickness of 60 nm. In view of the above, the first sidewall 21A has a height of 140 nm, and therefore the thickness of the region of the first gate interconnect formation film 22A that will be formed with the projection part 20A is half or more the height of the first sidewall 21A.

The metal film 33 deposited on the first gate interconnect formation film 22A to fully silicide the first gate interconnect formation film 22A has a thickness of 100 nm and is 1.1 times or more as thick as the region of the first gate interconnect formation film 22A that will be formed with the projection part 20A. In other words, nickel is higher in amount than silicon. In such a status, Ni₂Si and Ni₃Si are formed in silicidation of the first gate interconnect formation film 22A. The formation of Ni₂Si and Ni₃Si allows a part of the fully silicided first interconnect 18A formed with the projection part 20A to become approximately twice as thick as the first gate interconnect formation film 22A of polysilicon.

A region of the first gate interconnect formation film 22A on which associated one of the shared contact plugs 24 is to be formed, i.e., a region thereof that will be formed with the projection part 20A, has a thickness of 80 nm, and each first sidewall 21A has a height of 140 nm. Therefore, since the first interconnect 18A obtained by fully siliciding the first gate interconnect formation film 22A becomes approximately twice as thick as the first gate interconnect formation film 22A, it projects beyond the first sidewalls 21A. The projection part 20A of the first interconnect 18A extends also in a lateral direction and thus covers parts of the entire surfaces of the first sidewalls 21A. Likewise, the projection part 20B of the second interconnect 18B also projects beyond the second sidewalls 21B and thus covers parts of the entire surfaces of the second sidewalls 21B.

On the other hand, a region of the second gate interconnect formation film 22B on which no shared contact plug 24 is to be formed, i.e., a region thereof that will form the second gate electrode 17B, is etched to have a thickness of 40 nm. Therefore, even when the second gate interconnect formation film 22B is fully silicided, the second gate electrode 17B does not project beyond the second sidewalls 21B. Likewise, the first gate electrode 17A does not project beyond the first sidewalls 21A.

The polysilicon film 22, the silicon oxide film 23 and the metal film 33 need be appropriately changed in thickness according to change in the size of an element to be formed. An area of the entire surface of each first sidewall 21A covered with the projection part 20A can be adjusted by changing the ratio between the thickness of the polysilicon film 22 and that of the silicon oxide film 23.

Although in this embodiment two transistors are used as an example, other transistors may be formed on a semiconductor substrate. Other elements than transistors may be formed on the semiconductor substrate. An impurity diffusion layer connected through a shared contact plug to a gate electrode is not limited to one of source/drain diffusion layers and may be, for example, one of impurity diffusion layers that are components of a diode.

In this embodiment, the first gate interconnect 19A and the second gate interconnect 19B are formed of the polysilicon film 22. However, an amorphous silicon film may be used instead of the polysilicon film. Any other semiconductor material containing silicon may be used instead.

Although a nickel film is used as a material of the metal film 33 for full silicidation of gate interconnects, any other metal film, such as platinum, may be used instead. Furthermore, although nickel is used as a metal for forming silicide layers 16, a metal for silicidation, such as cobalt, titanium or tungsten, may be used instead. CVD may be used instead of sputtering to deposit the above-mentioned metal film.

Although a silicon nitride film is used for sidewalls, a layered structure of a silicon oxide film and a silicon nitride film may be used instead.

Although in this embodiment the underlayer protecting film 34 is formed to cover transistors, an underlayer protecting film 34 does not necessarily have to be formed. In this case, the interlayer dielectric 35 need be deposited on the third protective film 32 without etching the third protective film 32.

Although the underlayer protecting film 34 is deposited after etching of the third protective film 32, the underlayer protecting film 34 may be deposited before the deposition of the third protective film 32. In this case, when the top surface of the third protective film 32 is planarized and polished by CMP to expose the top ends of the first and second protective films 23A and 23B, a part of the underlayer protecting film 34 deposited above the first and second protective films 23A and 23B is also polished and removed.

### Embodiment 2

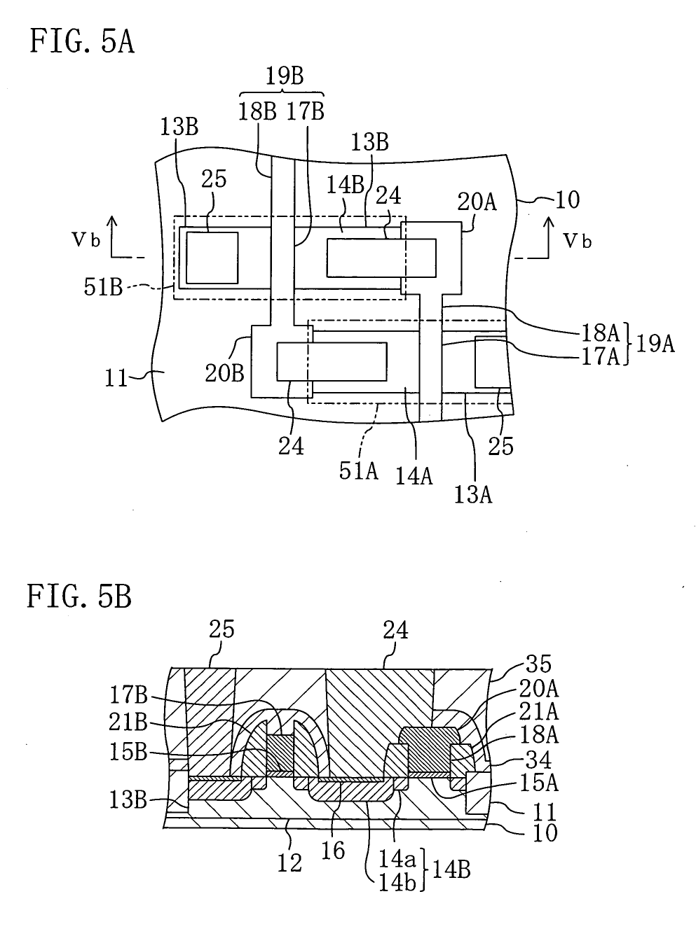

A second embodiment of the present invention will be described hereinafter with reference to the drawings. FIGS. 5A and 5B illustrate a semiconductor device according to the second embodiment of the present invention. FIG. 5A illustrates a plan structure of the semiconductor device, and FIG. 5B illustrates a cross-sectional structure thereof taken along the line Vb-Vb. In FIGS. 5A and 5B, the same components as those in FIGS. 1A and 1B are denoted by the same reference numerals, and thus description thereof is not given.

As illustrated in FIG. 5B, the semiconductor device of this embodiment is configured so that the height of a part of each of first sidewalls 21A formed on both sides of a part of a first interconnect 18A on which associated one of shared contact plugs 24 is formed is lower than that of a part of each of second sidewalls 21B formed on both sides of a second gate electrode 17B. Therefore, the first interconnect 18A can be easily formed, at its region on which the associated shared contact plug 24 is formed, with a projection part 20A. Furthermore, the projection part 20A can cover parts of the top surfaces of the first sidewalls 21A with reliability. The other structure of the semiconductor device is identical with that of the first embodiment.

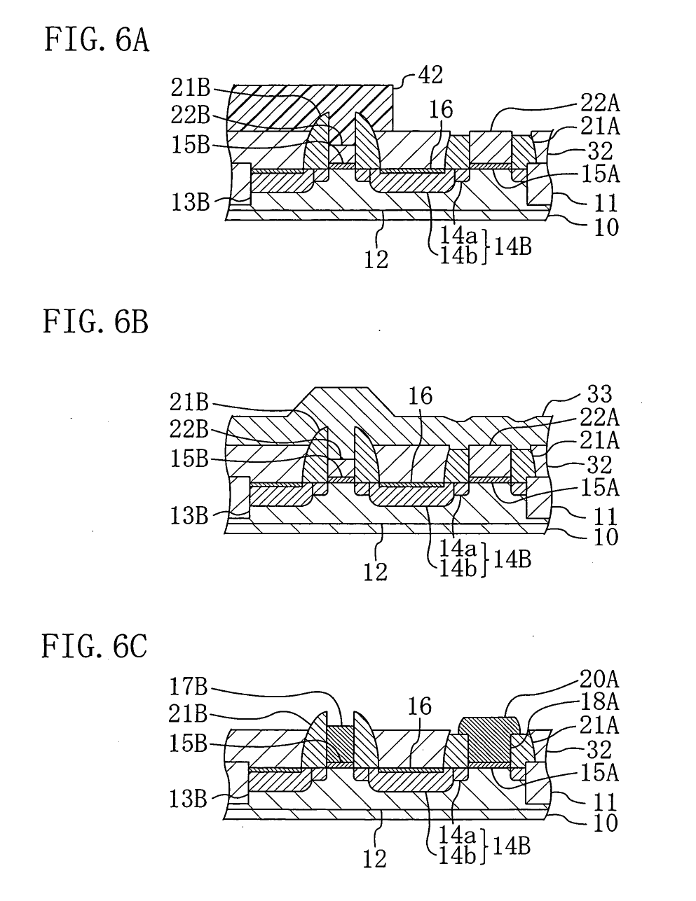

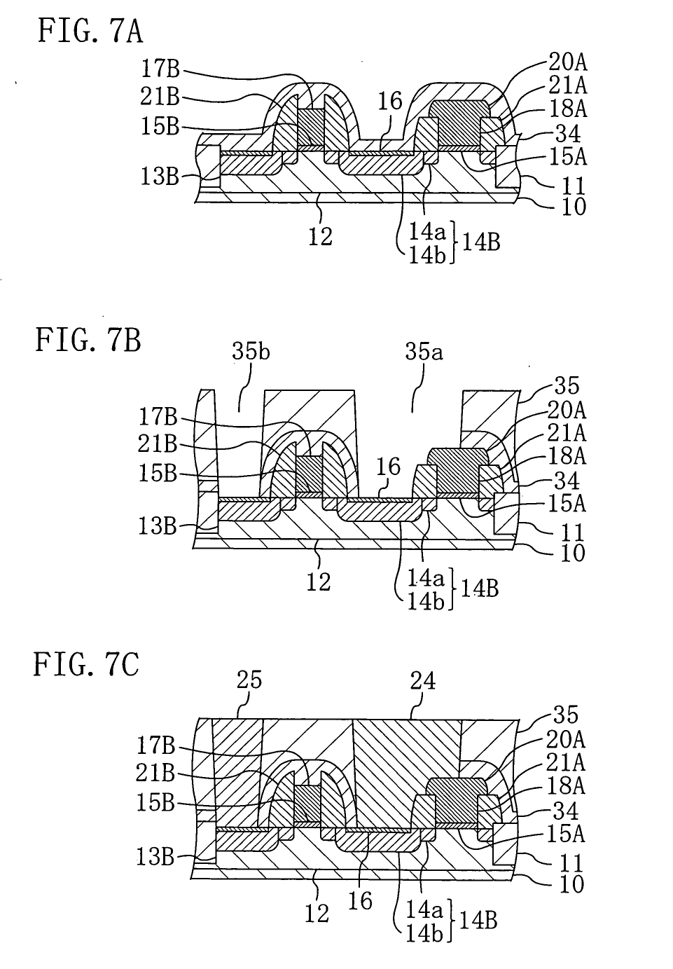

A fabrication method for a semiconductor device according to the second embodiment of the present invention will be described hereinafter with reference to the drawings. FIGS. 6A through 7C are cross-sectional views illustrating process steps in the fabrication method for a semiconductor device according to this embodiment. The process step of etching a second gate interconnect formation film 22B to reduce the thickness of the second gate interconnect formation film 22B to less than half the height of each of second sidewalls 21B and the previous process steps are identical with the process step illustrated in FIG. 3C and the previous process steps in the first embodiment. Therefore, their description is not given.

As illustrated in FIG. 6A, a resist mask 42 is formed to cover regions of the semiconductor substrate 10 on which gate electrodes are to be formed and expose the other region thereof on which gate interconnects each having a projection part are to be formed. Subsequently, exposed parts of the first and second sidewalls 21A and 21B located on both sides of regions of first and second gate interconnect formation film 22A and 22B that will be formed with projection parts 20A and 20B, respectively, are etched using the resist mask 42. This reduces the heights of the above-mentioned exposed parts of the first and second sidewalls 21A and 21B as compared with the other parts thereof. In other words, the height of a part of each of the first and second sidewalls 21A and 21B on which associated one of shared contact plugs 24 is to be formed is made lower than that of a part of each of the first and second sidewalls 21A and 21B formed on both sides of associated one of first and second gate electrodes 17A and 17B.

Next, as illustrated in FIG. 6B, the resist mask 42 is removed, and then a 100-nm-thick metal film 33 of nickel is deposited on a third protective film 32 by sputtering. Subsequently, the semiconductor substrate 10 is subjected to RTA in a nitrogen atmosphere at a temperature of 400° C. This causes reactions between the first gate interconnect formation film 22A and the metal film 33 and between the second gate interconnect formation film 22B and the metal film 33, resulting in the fully silicided first and second gate interconnect formation films 22A and 22B.

Next, as illustrated in FIG. 6C, unreacted part of the metal film 33 is removed. In this way, a fully silicided first gate interconnect 19A (see FIG. 5A) is formed of a first interconnect 18A having a projection part 20A that projects beyond the first sidewalls 21A and a first gate electrode 17A (see FIG. 5A) that does not project beyond the first sidewalls 21. Simultaneously, a fully silicided second gate interconnect 19B (see FIG. 5A) is formed of a second interconnect 18B (see FIG. 5A) having a projection part 20B (see FIG. 5A) that projects beyond the second sidewalls 21B and a second gate electrode 17B that does not project beyond the second sidewalls 21B.

Next, as illustrated in FIG. 7A, the third protective film 32 is removed by dry etching or wet etching. Thereafter, a 50-nm-thick underlayer protecting film 34 made of a silicon nitride film is deposited, for example, by CVD to entirely cover the semiconductor substrate 10.

Next, as illustrated in FIG. 7B, an interlayer dielectric 35 made of a silicon oxide film is formed on the underlayer protecting film 34, for example, by CVD, and then the top surface of the interlayer dielectric 35 is planarized by CMP. Thereafter, a resist mask (not shown) is formed on the interlayer dielectric 35, and then the interlayer dielectric 35 and the underlayer protecting film 34 are subjected to dry etching using the resist mask. In this way, a first contact hole 35a is formed to expose part of associated one of the silicide layers 16 formed on the deep source/drain diffusion layers 14b, part of associated one of the first sidewalls 21A, and part of the projection part 20A of the first interconnect 18A. Simultaneously, a second contact hole 35b is formed to expose part of the other one of the silicide layers 16.

Next, as illustrated in FIG. 7C, the first and second contact holes 35a and 35b are filled with a conductive material, such as tungsten, as in the first embodiment. In this way, a shared contact plug 24 is formed so as to be connected to associated one of the silicide layers 16 formed on the deep source/drain diffusion layers 14b and the first interconnect 18A. Simultaneously, a contact plug 25 is formed so as to be connected to the other one of the silicide layers 16.

According to the method of this embodiment, the height of a region of each of the first sidewalls 21A formed on both sides of a part of the first interconnect 18A on which the shared contact plug 24 is formed is made lower than that of the other region thereof. Therefore, a first gate interconnect 19A can be easily formed of a first interconnect 18A having a projection part 20A and a first gate electrode 17A having no projection part. Furthermore, the second sidewalls 21B are also allowed to have the same structure. Therefore, a second gate interconnect 19B can be easily formed of a second interconnect 18B having a projection part 20B and a second gate electrode 17B having no projection part.

In view of the above, one of the first sidewalls 21A can be restrained from being etched in the formation of the first contact hole 35a for forming a shared contact plug 24. This can restrain a leakage current from being produced due to a short circuit between the shared contact plug 24 and associated one of the shallow source/drain diffusion layers 14a.

The amount to which respective regions of the first sidewalls 21A to be covered with the projection part 20A are etched need be determined based on the thickness of a region of the first gate interconnect formation film 22A that will be formed with the projection part 20A and other elements. In this case, the top surface of the region of the first gate interconnect formation film 22A that will be formed with the projection part 20A is allowed to be at a lower level than the top end of a region of each of the first sidewalls 21A covered with the projection part 20A. Therefore, it becomes easy to partially cover the surfaces of the first sidewalls 21A. The height of each of the etched first sidewalls 21A is preferably larger than the thickness of the underlayer protecting film 34.

Although in this embodiment the second gate interconnect formation film 22B and the first sidewalls 21A are etched in this order, they may be etched in the opposite order.

As described above, the present invention is useful as a semiconductor device whose gate interconnect is fully silicided and has a local interconnect structure and a method for fabricating the same.

What is claimed is:

1. A semiconductor device comprising:
an isolation region formed in a semiconductor substrate;
an active region formed in the semiconductor substrate so as to be surrounded by the isolation region;
a fully silicided first gate interconnect formed on the semiconductor substrate;
an insulative first sidewall formed on a side of the first gate interconnect;
impurity diffusion layers formed in the active region;
an interlayer dielectric formed on the semiconductor substrate to have an opening exposing an area covering a part of the first gate interconnect and a part of associated one of the impurity diffusion layers; and
a contact plug made of a conductive material with which the opening is filled and connected to the first gate interconnect and the associated impurity diffusion layer,
the first gate interconnect being formed, at its part connected to the contact plug, with a projection part projecting beyond the first sidewall.

2. The semiconductor device of claim 1, wherein
the projection part of the first gate interconnect covers part of the entire surface of the first sidewall.

3. The semiconductor device of claim 1, wherein
the first gate interconnect includes a first gate electrode and a first interconnect formed continuously with the first gate electrode,
the contact plug is connected to the first interconnect,
the first interconnect is formed, at its part connected to the contact plug, with the projection part, and
the height of the first gate electrode is equal to or lower than that of the first sidewall.

4. The semiconductor device of claim 3, wherein
the height of a part of the first sidewall formed on a side of a part of the first interconnect formed with the projection part is lower than that of a part of the first sidewall formed on a side of the first gate electrode.

5. The semiconductor device of claim 1, wherein
the first gate interconnect is formed on the active region with a first gate insulating film interposed therebetween.

6. The semiconductor device of claim 1 further comprising:
a fully silicided second gate interconnect formed on the semiconductor substrate at some distance from the first gate interconnect;
a second gate insulating film formed on the active region and under the second gate interconnect; and
an insulative second sidewall formed on a side of the second gate interconnect,
wherein the associated impurity diffusion layer is a source/drain region formed in a region of the active region between the second gate interconnect and the first gate interconnect.

7. The semiconductor device of claim 6, wherein
the source/drain region includes a first diffusion layer formed in a region of the active region located to a side of the second gate interconnect and a second diffusion layer formed in a region of the active region located further from the second gate interconnect than the first diffusion layer and deeper than the first diffusion layer, and
the contact plug is electrically connected to the second diffusion layer.

8. The semiconductor device of claim 6, wherein
the second gate interconnect includes a second gate electrode and a second interconnect formed continuously with the second electrode,
the second gate electrode is formed on the second gate insulating film, and
the height of the second gate electrode is equal to or lower than that of the second sidewall.

9. The semiconductor device of claim 1, wherein
the first gate interconnect is made of nickel silicide.

10. The semiconductor device of claim 1 further comprising
an underlayer protecting film formed between the interlayer dielectric and the semiconductor substrate.

11. The semiconductor device of claim 1, wherein
the contact plug is electrically connected through a silicide layer to the associated impurity diffusion layer.

12. A method for fabricating a semiconductor device, said method comprising the steps of:
(a) forming an isolation region in a semiconductor substrate and forming an active region in the semiconductor substrate so as to be surrounded by the isolation region;
(b) after the step (a), forming a first gate interconnect formation film made of a semiconductor material containing silicon on the semiconductor substrate;
(c) forming an insulative first sidewall on a side of the first gate interconnect formation film;
(d) after the step (b), forming impurity diffusion layers in the active region;
(e) after the steps (c) and (d), fully siliciding the first gate interconnect formation film, thereby forming a first gate interconnect; and
(f) after the step (e), forming an interlayer dielectric to entirely cover the semiconductor substrate;
(g) etching the interlayer dielectric, thereby forming an opening in a region of the interlayer dielectric covering a part of the first gate interconnect and a part of associated one of the impurity diffusion layers; and
(h) filling the opening with a conductive material, thereby forming a contact plug electrically connected to the first gate interconnect and the associated impurity diffusion layer,
wherein in the step (e), the first gate interconnect is formed, at its part connected to the contact plug, with a projection part projecting beyond the first sidewall.

13. The method of claim 12, wherein
in the step (e), the projection part of the first gate interconnect is formed to cover a part of the entire surface of the first sidewall.

14. The method of claim 12, wherein
in the step (e), the first gate interconnect formation film is formed into the first gate interconnect formed of a first gate electrode and the first gate interconnect formed continuously with the first gate electrode,
the method further comprises the step of (i) between the steps (d) and (e), etching a part of the first gate interconnect formation film that will be a first gate electrode, thereby allowing the part of the first gate interconnect formation film that will be a first gate electrode to become thinner than a part of the first gate interconnect formation film that will be a part of the first interconnect formed with the projection part, and
in the step (e), the height of the first gate electrode is equal to or lower than that of the first sidewall.

15. The method of claim 14, wherein
in the step (i), the thickness of a part of the first gate interconnect formation film that will become a part of the first gate interconnect formed with the projection part is more than half the height of the first sidewall.

16. The method of claim 14, wherein
in the step (i), the thickness of a part of the first gate interconnect formation film that will become the first gate electrode is less than half the height of the first sidewall.

17. The method of claim 14 further comprising the step of
(j) between the steps (i) and (e), allowing the height of a part of the first sidewall formed on the side of the part of the first gate interconnect formation film that will be a part of the first gate interconnect formed with the projection part to have a lower height than that of the first sidewall formed on a side of the part of the first gate interconnect formation film that will be the first gate electrode.

18. The method of claim 17, wherein
in the step (j), the height of a region of the first sidewall on which the projection part is to be formed is lower than that of an associated region of the first gate interconnect formation film.

19. The method of claim 12 further comprising the step of
(k) between the steps (e) and (f), forming an underlayer protecting film to entirely cover the semiconductor substrate,
wherein in the step (f), the interlayer dielectric is formed to cover the underlayer protecting film.

20. The method of claim 12, wherein
in the step (b), a second gate interconnect formation film made of a semiconductor material containing silicon is formed on the semiconductor substrate at some distance from the first gate interconnect formation film,
in the step (c), an insulative second sidewall is formed on a side of the second gate interconnect formation film,
in the step (d), the impurity diffusion layers are formed in regions of the active region located to both sides of the second gate interconnect formation film, and
in the step (e), the second gate interconnect formation film is fully silicided, thereby forming a second gate interconnect.

21. The method of claim 20 further comprising the step of
(l) between the steps (a) and (b), forming a gate insulating film on the active region,
wherein in the step (b), the first and second gate interconnect formation films are formed on the active region with the gate insulating film interposed between a combination of the first and second gate interconnect formation films and the active region.
